(19) United States
(12) Patent Application Publication
(10) Pub. No.: US 2013/0033161 A1
(43) Pub. Date: Feb. 7, 2013

(54) SLIDING MECHANISM AND PORTABLE DEVICE

(71) Applicant: Takeharu Kitagawa, Tokyo (JP)

(72) Inventor: Takeharu Kitagawa, Tokyo (JP)

(73) Assignee: NEC CORPORATION, Tokyo (JP)

(21) Appl. No.: 13/640,470

(22) PCT Filed: Apr. 7, 2011
(86) PCT No.: PCT/JP2011/002075

§ 371 Date: Oct. 10, 2012

(30) Foreign Application Priority Data
May 20, 2010 (JP) 2010-116124

(51) Int. Cl. H04M 1/03; H05K 5/03

(52) U.S. Cl. 312/294; 74/100.2

(57) ABSTRACT

A sliding mechanism includes a first frame provided with a rail having a sliding direction that changes; a second frame that slides along the rail; a link that is mounted on the rail and the second frame and rotates to change a tilt angle of the first frame with respect to the second frame; a first stopper that regulates the rotation of the link; and a second stopper that regulates the rotation of the link from a direction different from that of the first stopper.

### TECHNICAL FIELD

The present invention relates to a sliding mechanism and a portable device, and more particularly, to a sliding mechanism having a tilting structure, and a portable device.

### BACKGROUND ART

In recent years, a slide-type mobile phone, which is one of portable devices, can be used in both an open state and a closed state, in the case of using a telephone call function, a mail function, a menu function, an Internet function, a game function, a camera function, a music function, a television function, and the like.

FIG. 22A shows a closed state of a slide-type mobile phone disclosed in Patent literature 1. FIG. 22B shows an open state of the slide-type mobile phone disclosed in Patent literature 1. In the open state, a casing 110 including a display unit slides with respect to a casing 120 including keys. Further, the casing 110 is tilted at a predetermined tilt angle with respect to the casing 120. This tilt angle is about 3 to 10 degrees, for example.

Patent literatures 2 to 5 disclose other structures for providing a tilt angle. FIG. 23 shows a slide-type mobile phone that is brought into an open state so as to make a call. A tilt angle allows the mobile phone to fit the face, which facilitates the use of the mobile phone. FIG. 24A shows a state where the mobile phone is opened to send an e-mail. A tilt angle allows a user to easily view the screen.

### CITATION LIST

### Patent Literature

Patent literature 1: Japanese Unexamined Patent Application Publication No. 2006-186577

Patent literature 2: Japanese Unexamined Patent Application Publication No. 2007-74411

Patent literature 3: Japanese Unexamined Patent Application Publication No. 2007-132508

Patent literature 4: Japanese Unexamined Patent Application Publication No. 2009-71511

Patent literature 5: Japanese Unexamined Patent Application Publication No. 2009-88667

### SUMMARY OF INVENTION

### Technical Problem

However, in the case of using a mobile phone in a crowded train, for example, a user's arm is bent to a greater degree as shown in FIG. 24B. There is a limitation on the flipping motion of a wrist. When the casing 110 is tilted with respect to the casing 120, the screen is too close to the user's face. This makes it difficult for the user to view the display screen.

As shown in FIG. 24C, Patent literature discloses a structure in which the tilt angle is set to 0 degrees. In the structures disclosed in Patent literatures 3 to 5, however, the structure for setting the tilt angle to 0 degrees is complicated, and thus the operation is troublesome. In Patent literature 5, for example, an operation for changing the tilt angle is performed once in the case of returning the mobile phone to the closed state, thereby making the casings parallel to each other. After that, an operation for allowing the casings to slide is carried out.

The present invention has been made in view of the above-mentioned problem, and an object of the present invention is to provide a sliding mechanism and a portable device which are capable of changing a tilt angle with a simple configuration.

### Solution to Problem

A sliding mechanism according to an aspect of the present invention includes: a first frame provided with a slide rail having a sliding direction that changes; a second frame that slides along the slide rail; an elastic member that generates an urging force between the first frame and the second frame according to a slide position of each of the first frame and the second frame; a link that is mounted slidably with respect to the slide rail and rotates to change a tilt angle of the first frame with respect to the second frame; a first stopper that regulates the rotation of the link; and a second stopper that regulates the rotation of the link from a direction different from that of the first stopper.

### Advantageous Effects of Invention

According to the present invention, it is possible to provide a sliding mechanism and a portable device which are capable of changing a tilt angle with a simple configuration.

### BRIEF DESCRIPTION OF DRAWINGS

FIG. 1A is a perspective view showing a configuration of a mobile phone according to this exemplary embodiment when the mobile phone is in a closed state;

FIG. 1B is a perspective view showing the configuration of the mobile phone according to this exemplary embodiment when the mobile phone is in an open state;

FIG. 2 is an exploded perspective view showing a configuration of a slide-type mobile phone according to this exemplary embodiment;

FIG. 3 is an exploded perspective view showing a configuration of a hinge unit;

FIG. 4A is a first enlarged schematic view showing a mechanism in the periphery of a link;

FIG. 4B is a second enlarged schematic view showing a mechanism in the periphery of a link;

FIG. 5 is a perspective view showing a configuration of a first frame;

FIG. 6 is a perspective view showing a configuration of a slide rail;

FIG. 7 is a perspective view showing a configuration of a link;

FIG. 8 is a perspective view showing a configuration of a second frame;

FIG. 9 is a perspective view showing a configuration of an assist spring;

FIG. 10 is a perspective view showing a configuration of a second spring base;

FIGS. 11 are perspective views for explaining a sliding action of a mobile phone;

FIGS. 12 are perspective views for explaining a sliding action and a tilting action of a mobile phone;

FIGS. 13 are perspective views for explaining the sliding action and the tilting action of the mobile phone;

FIG. 14A is a schematic view showing a link angle of a sliding mechanism;

FIG. 14B is a schematic view showing a tilt angle of the sliding mechanism;

FIG. 15A is an enlarged schematic view showing a configuration of a substantial part of the sliding mechanism in a high tilt angle state;

FIG. 15B is an enlarged schematic view showing a configuration of a substantial part of the sliding mechanism in a low tilt angle state;

FIG. 16A is a first side sectional view for explaining the tilting action of the sliding mechanism;

FIG. 16B is a second side sectional view for explaining the tilting action of the sliding mechanism;

FIG. 16C is a third side sectional view for explaining the tilting action of the sliding mechanism;

FIG. 16D is a four side sectional view for explaining the tilting action of the sliding mechanism;

FIG. 17 are perspective views for explaining a sliding action of a mobile phone according to a second exemplary embodiment;

FIG. 18 are perspective views for explaining a sliding action and a tilting action of the mobile phone according to the second exemplary embodiment;

FIG. 19 are perspective view for explaining the sliding action and the tilting action of the mobile phone according to the second exemplary embodiment;

FIG. 20A is a first enlarged schematic view showing a configuration of a substantial part of a sliding mechanism according to the second exemplary embodiment of the present invention;

FIG. 20B is a second enlarged schematic view showing a configuration of a substantial part of the sliding mechanism according to the second exemplary embodiment of the present invention;

FIG. 21 is a perspective view showing a configuration of a second spring base according to the second exemplary embodiment;

FIG. 22A is a first view showing a tilting mechanism of a mobile phone disclosed in Patent literature 1;

FIG. 22B is a second view showing the tilting mechanism of the mobile phone disclosed in Patent literature 1;

FIG. 23 is a view showing the mobile phone disclosed in Patent literature 1;

FIG. 24A is a first view showing a tilting action disclosed in Patent literature 1;

FIG. 24B is a second view for explaining the tilting action disclosed in Patent literature 1; and

FIG. 24C is a third view for explaining the tilting action disclosed in Patent literature 1.

### DESCRIPTION OF EMBODIMENTS

Hereinafter, exemplary embodiments of the present invention will be described. Note that the size and ratio of each component shown in the attached drawings are illustrated for convenience of explanation, and are not necessarily the same as the actual size and ratio.

### First Exemplary Embodiment

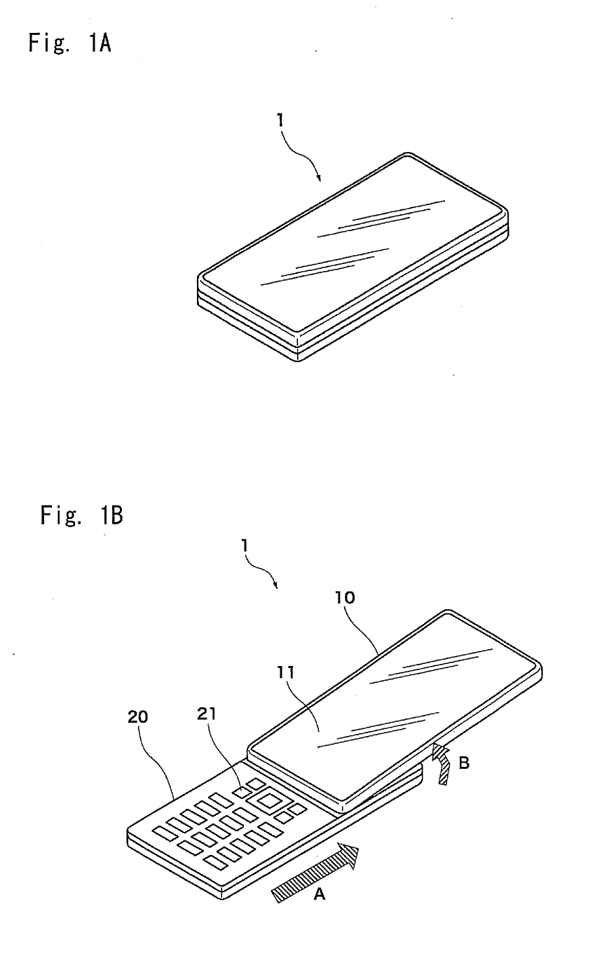

FIGS. 1A and 1B are perspective views each showing a configuration of a mobile phone which is an example of a portable device according to an exemplary embodiment of the present invention. The mobile phone according to this exemplary embodiment is a slide-type mobile phone 1. FIG. 1A shows a state in which the mobile phone is closed (hereinafter referred to as a closed state), and FIG. 1B shows a state in which the mobile phone is opened (hereinafter referred to as an open state). The mobile phone includes a first casing 10 and a second casing 20. The first casing 10 is provided with a display unit 11. The display unit 11 includes a display device such as a liquid crystal display or an organic EL display. The second casing 20 is provided with an input unit 21 including input keys and the like. The first casing 10 and the second casing 20 incorporate major components, such as a microphone, a speaker, a memory, an antenna, a battery, semiconductor components necessary for communication and software operations, a substrate having these components mounted thereon, an external connection connector, and a vibration motor, so as to implement various functions (a telephone call function, a mail function, a menu function, an Internet function, a game function, a camera function, a music function, a television function, and the like) of the mobile phone.

The first casing 10 and the second casing 20 have a substantially rectangular parallelepiped shape and substantially the same size. In the closed state, the first casing 10 and the second casing 20 overlap each other, and the first casing 10 and the second casing 20 do not protrude from each other. In other words, in the closed state, the outer shape of the mobile phone 1 is a substantially rectangular parallelepiped. The display unit 11 is disposed on a front surface side (on a surface opposite to the second casing of the first casing 10), and is visible in both the open state and the closed state. An input unit 21 is disposed on a surface at the first casing side of the second casing 20. Accordingly, in the closed state, the input unit 21 is opposed to the back surface of the first casing 10 and thus is hidden.

The first casing 10 is slidably supported in a direction indicated by an arrow A with respect to the second casing 20. Specifically, the second casing 20 is slidably provided along slide rails (not shown in FIGS. 1A and 1B) which are provided to the first casing 10. Accordingly, when a force is applied to the first casing 10 in the state where a user grips the second casing 20, the first casing 10 slides. As a result, the mobile phone 1 shifts from the open state to the closed state, or vice versa. In the following description, a sliding direction upon shifting from the closed state to the open state is referred to as an extending direction, and a sliding direction upon shifting from the open state to the closed state is referred to as a retracting direction. The mobile phone 1 is in the open state at one end of the slide position, and is in the closed state at the other end of the slide position. In other words, the mobile phone is in the open state when the mobile phone moves to a first slide end, and is in the closed state when the mobile phone moves to a slide end on the opposite side of the first slide end. In this manner the mobile phone 1 changes from the open state to the closed state depending on a sliding range of a sliding mechanism.

Note that the input unit 21 appears in the open state, which allows the user to manipulate the input keys and the like. The sliding direction parallel with the display unit 11 is defined as the lengthwise direction of the mobile phone 1. The direction perpendicular to the display surface of the display unit 11 is defined as the thickness direction of the mobile phone 1. Further, the direction perpendicular to each of the lengthwise direction and the thickness direction is defined as the width direction of the mobile phone 1.

The mobile phone 1 has a tilting mechanism. Accordingly, when the first casing 10, which is in parallel with the second casing 20 in the closed state, shifts to the open state, the first casing is tilted in a direction indicated by an arrow B. As the first casing 10 is caused to further slide, the first casing 10 is gradually tilted with respect to the second casing 20 during the sliding. Thus, the mobile phone 1 has a tilt-sliding mechanism.

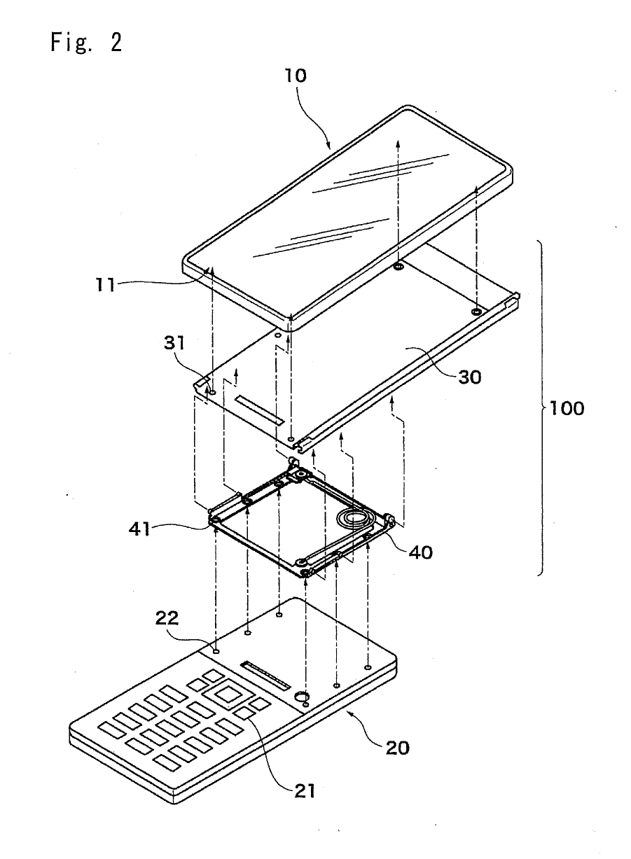

Referring next to FIG. 2, the sliding mechanism of the mobile phone 1 will be described. FIG. 2 is an exploded perspective view showing the configuration of the mobile phone. A first frame 30 is mounted on the back surface of the first casing 10. The first frame 30 is provided with screw holes 31. The first frame 30 and the first casing 10 are screwed using the screw holes 31 and screw bosses (not shown) which are formed on the back surface side of the first casing 10.

Screw holes 22 are formed in the front surface of the second casing 20. Screw bosses 41 are formed on a second frame 40. The second frame 40 and the second casing 20 are screwed using the screw holes 22 and the screw bosses 41. Each of the first frame 30 and the second frame 40 is a hinge frame that constitutes a hinge unit 100. The hinge unit 100 is a sliding mechanism with a tilt (tilt-sliding mechanism). That is, the first frame 30 is tilted with respect to the second frame 40. The second frame 40 slidably supports the first frame 30. A relative position of the first frame 30 relative to the second frame 40 is changed, thereby allowing the mobile phone 1 to perform a sliding action. In other words, when the first frame 30 is caused to slide with respect to the second frame 40, the first casing 10 mounted on the first frame 30 slides with respect to the second casing 20 mounted on the second frame 40. Since the first frame 30 and the second frame 40 slide relatively to each other, when one frame is gripped, the other frame slides.

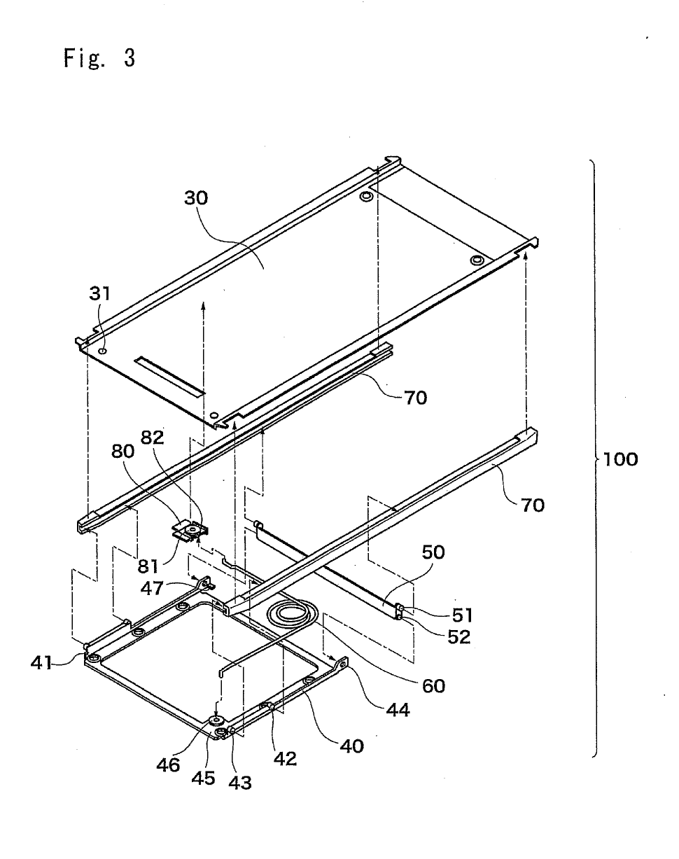

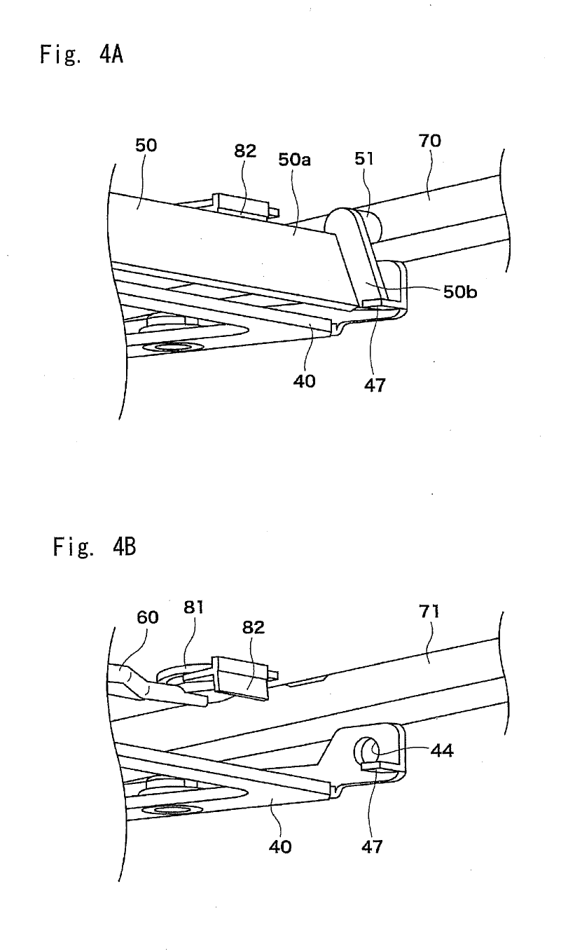

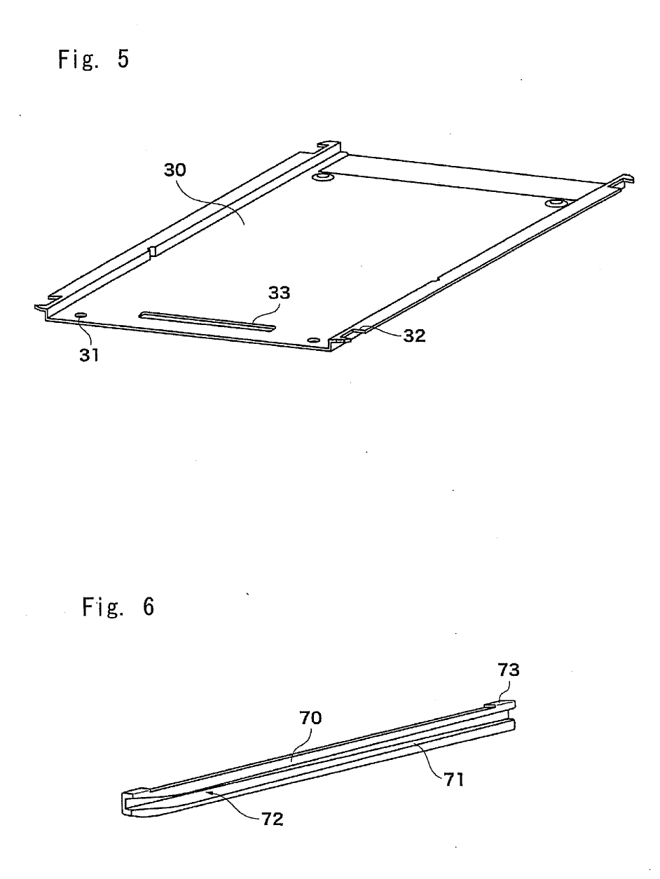

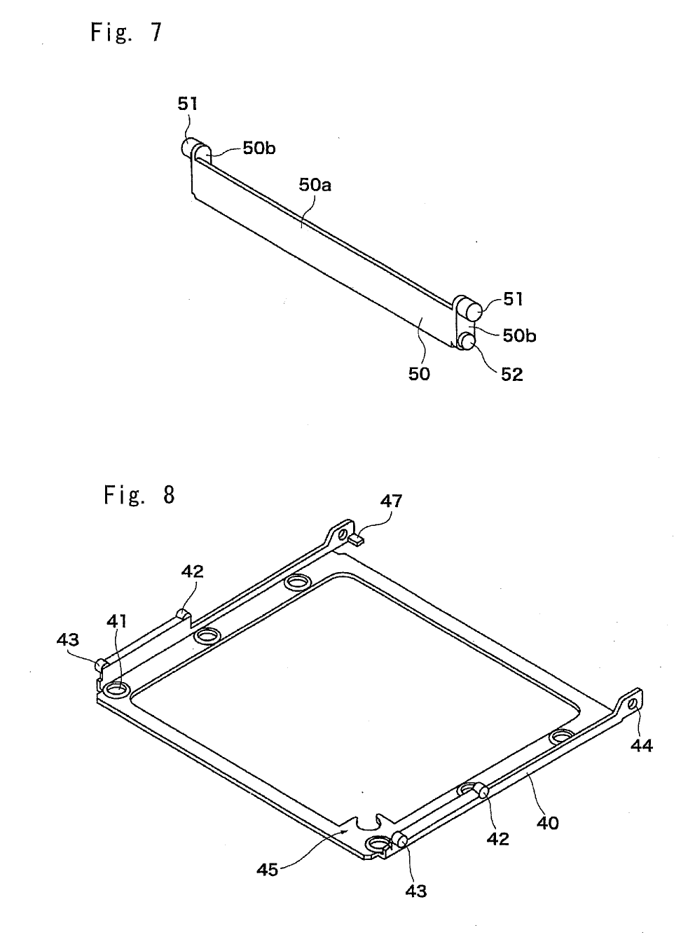

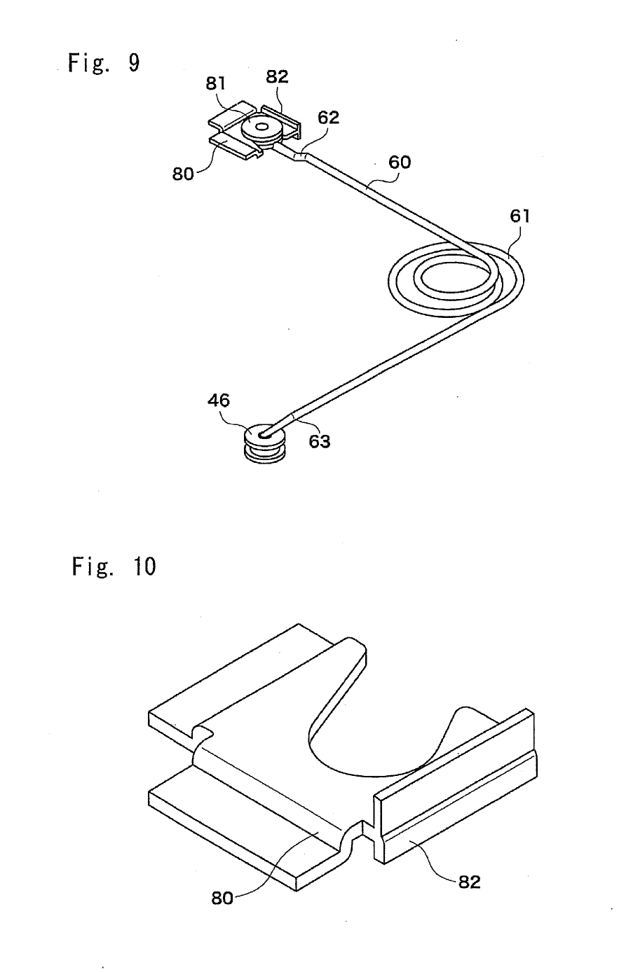

Next, a detailed configuration of the hinge unit 100 will be described with reference to FIGS. 3 to 10. FIG. 3 is an exploded perspective view showing the configuration of the hinge unit 100. As shown in FIG. 3, the hinge unit 100 includes the first frame 30, the second frame 40, a link 50, an assist spring 60, rails 70, and a first spring base 80. FIGS. 4A and 4B are enlarged perspective views each showing a configuration in the vicinity of the link 50 of the hinge unit. FIG. 4A shows a state where the link 50 and a stopper are in contact with each other. FIG. 4B shows a state where the link 50 is omitted for ease of explanation. FIG. 5 is a perspective view showing the configuration of the first frame 30. FIG. 6 is a perspective view showing the configuration of the rail 70. FIG. 7 is a perspective view showing the configuration of the link 50. FIG. 8 is a perspective view showing the configuration of the second frame 40. FIG. 9 is a perspective view showing the configuration of the assist spring 60 which is mounted with a spring support. FIG. 10 is a perspective view showing the configuration of the first spring base 80. The following description will be made with reference to the figures illustrating the components, as needed.

The first frame 30 is a plate-like member with both ends rising upward. Accordingly, L-shaped side walls are formed at both ends of the flat plate. The first frame 30 is for example, a sheet metal press work, a metal molded product, a resin molded product, or an integrally molded product of metal and resin. In this case, the first frame 30 is a sheet metal part having a U-shaped cross section with both sides folded into an L-shape. The first frame 30 is provided with the screw holes 31, notches 32, and a long hole 33. The central long hole 33 is a through-hole formed in a flexible substrate. Specifically, FTCs (Flexible Printed Circuits) or the like to be connected with electronic circuits or the like provided in the first casing 10 are inserted into the long hole 33. The flexible substrate is used to transmit electrical signals between the first casing 10 and the second casing 20, for example.

The rails 70 are respectively provided at both ends of the first frame 30. The rails 70 are rod-like members each having a longitudinal direction. The two rails 70 are members having substantially the same shape. A groove 71 extending along the longitudinal direction is formed on one surface of each of the rails 70. Each of the rails 70 is, for example, a metal sheet press-forged product, a metal molded product, a resin molded product, or an integrally molded product of metal and resin. In this case, each of the rails 70 is a metal sheet forged part having a U-shaped cross section. The two rails 70 are arranged in parallel along the sliding direction. The second frame 40 slides and moves along the rails 70. As shown in FIG. 6, each of the rails 70 is provided with a positioning portion 73. The positioning portion 73 is aligned with the corresponding notch 32, thereby allowing each rail 70 to be mounted on the first frame 30 with a high positioning accuracy. The first frame 30 and the rails 70 are connected together by welding, screwing, integral molding, or the like.

The pair of rails 70 is arranged side by side such that the grooves 71 face each other. First pins 51, second pins 42, and third pins 43 are disposed in the grooves 71 that are formed in the rails 70. The first pins 51, the second pins 42, and the third pins 43 slide along the rails 70. This allows the second frame 40 to slide with respect to the first frame 30. Further, a curved portion 72 is provided to each of the grooves 71 of the rails 70 to carry out a tilting action. Specifically, the direction of each groove 71 changes at the curved portion 72, and thus each groove 71 is formed in a doglegged shape. In the case of sliding and moving to the open state, the position of each of the first pins 51 is away from the second casing 20, for example, in the thickness direction of the mobile phone 1. In the thickness direction of the mobile phone 1, the leading end of the first casing 10 slides away from the second casing 20. In this manner, the tilt sliding action is carried out.

Assume herein that each of the grooves 71 has a linear portion 71a which is located on the right side of the curved portion 72, and a tilted portion 71b which is located on the left side of the curved portion 72. In the closed state, the linear portion 71a is in substantially parallel with the front surface of the second casing 20. The tilted portion 71b is tilted with respect to the linear portion 71a. In the closed state, the first pins 51, the second pins 42, and the third pins 43 are located at the linear portion 71a. This allows the first pins 51, the second pins, and the third pins 43 to be arranged at the same height as the front surface of the second casing 20. In the open state, the first pins 51 are located at the linear portion 71a; the second pins 42 are located at the vicinity of the curved portion 72; and the third pins 43 are located at the tilted portion 71b. Thus, the height of each first pin 51 with respect to the front surface of the second casing 20 is different from the height of each of the second pins 42 and the third pins 43. Accordingly, in the open state, the first casing 10 is tilted with respect to the second casing 20. When each of the third pins 43 passes through the linear portion 71a and moves toward the curved portion 72, the height of the first pins 51 increases. In other words, the distance in the thickness direction from the front surface of the second casing 20 to each first pin 51 increases. As a result, the first casing 10 is gradually tilted with respect to the second casing 20 in the middle of the sliding action.

The link 50 is connected to the two rails 70. Specifically, the link 50 is slidably mounted to the rails 70. The link 50 is, for example, a sheet metal press work, a metal molded product, a resin molded product, or an integrally molded product of metal and resin. In this case, the link 50 is a plate-like metal part. The link 50 is a member having a longitudinal direction, and is disposed perpendicularly to the rails 70. Accordingly, one end of the link 50 is mounted on one of the rails 70, and the other end of the link 50 is mounted on the other rail 70. As shown in FIG. 7, the link 50 has a base portion 50a and ribs 50b. The base portion 50a is a portion formed along a direction perpendicular to the rails 70, that is, along the width direction of the mobile phone 1. The ribs 50b are respectively provided at both ends of the base portion 50a. The first pins 51 and shafts 52 project from the two ribs 50b. Each of the first pins 51 and the shafts 52 has a cylindrical shape projecting outward from each of the ribs 50b.

Thus, the first pins 51 and the shafts 52 are disposed at both ends of the link 50. The first pins 51 are inserted into the respective grooves 71. The width of each of the grooves 71 and the diameter of each of the first pins 51 are designed so as to provide a slight clearance to each groove 71. This allows the first pins 51 to slide with respect to the respective grooves 71. Each of the first pins 51 is, for example, a sheet metal press work, a metal molded product, a resin molded product, or an integrally molded product of metal and resin. The link 50 and the first pins 51 are connected together by an integral product, welding, placing, or the like. The first pin 51 and the shaft 52 are arranged side by side on each of the ribs 50b. Each shaft 52 is disposed at a position closer to the second frame 40 than the corresponding first pin 51. The height of each shaft 52 is lower than that of each of the first pins 51. The shafts 52 are inserted into respective shaft holes 44 of the second frame 40. The link 50 is decentered with respect to each shaft 52.

The second frame 40 is a frame-like member with both ends rising and being in close contact with the rails 70. The second frame 40 is, for example, a sheet metal press work, a metal molded product, a resin molded product, or an integrally molded product of metal and resin. The second frame 40 is disposed below the first frame 30. The second frame is provide with the screw bosses 41, the second pins 42, the third pins 43, the shaft holes 44, a second spring base 45, and a first stopper 47. The second pins 42 are respectively provided at both ends of the second frame 40. Also the third pins 43 are respectively provided at both ends of the second frame 40. Each of the second pins 42 and the third pins 43 has a cylindrical shape projecting outward. Each of the second pins 42 and the third pins 43 project to the inside of the grooves 71, and slides with respect to the grooves 71. That is, the second pins 42 and the third pins 43 are inserted into the grooves 71 as described above. In each of the grooves 71, each of the second pins 42 is disposed between the corresponding third pin 43 and the corresponding first pin 51. Each of the second pins 42 and the third pins 43 is, for example, a sheet metal press work, a metal molded product, a resin molded product, or an integrally molded product of metal and resin. The second frame 40, the second pins 42, and the third pins 43 are connected together by an integral product, welding, placing, or the like.

The first pins 51, the second pins 42, and the third pins 43 are slidably connected to the grooves 71 of the rails 70. That is, the second frame 40 slides with respect to the rails 70 that are formed on the first frame 30.

The two shaft holes 44 are formed in the second frame 40. The two shaft holes 44 are coaxially arranged in the vicinity of the corners of the second frame 40. As described above, the shafts 52 of the link 50 are inserted into the respective shaft holes 44. The link 50 rotates with respect to the second frame 40 with the central axis of the column of each shaft 52 as a rotation axis. In other words, the second frame 40 rotatably supports the link 50. When the link 50 is allowed to rise, the tilt angle increases, and when the link 50 is allowed to fall, the tilt angle decreases. The second frame 40 is also provided with the first stopper 47 for controlling the tilt angle. The first stoppers 47 are disposed in the vicinity of each of the shaft holes 44. The first stopper 47 contacts the link 50, thereby regulating the rotation of the link 50. This enables limitation of the tilt angle.

Furthermore, the second spring base 45 is provided in the vicinity of a corner of the second frame 40. The second spring base 45 is formed of a part of the second frame 40. The second spring base 45 is mounted with a second spring support 46 that receives the assist spring 60. The second spring support 46 is a metal molded product, a resin molded product, or the like. The second spring base 45 and the second spring support 46 are connected together by fitting. The second spring support 46 is connected with the assist spring 60.

In the second spring base 45, the assist spring 60 is mounted on the second frame 40 through the second spring support 46. The assist spring 60 is a metal product. The assist spring 60 and the second spring support 46 are connected together by fitting. The assist spring 60 is an elastic member that generates an urging force depending on the slide position. Specifically, the assist spring 60 generates an urging force in the direction in which the sliding operation of the user is assisted. An urging force may be generated between the first frame 30 and the second frame 40 by using an elastic member other than a spring.

At the center of the assist spring 60, a spiral portion 61 which is obtained by winding a metal line in a spiral shape is formed. The metal line extends substantially linearly from the spiral portion 61 to one end 62 of the assist spring 60. Further, the metal line extends substantially linearly from the spiral portion 61 to the other end 63 of the assist spring 60. The metal line extending from the spiral portion 61 to the one end 62 and the metal line extending from the spiral portion 61 to the other end 63 are inclined. Here, the metal line extending from the spiral portion 61 to the one end 62 and the metal line extending from the spiral portion 61 to the other end 63 are substantially orthogonal to each other and form an L-shape. The spiral portion 61 is disposed at the corner of the L-shape. The other end 63 of the assist spring 60 is connected with the second spring support 46.

The one end 62 of the assist spring 60 is connected with a first spring support 81. The leading end of the assist spring 60 is inserted into a hole formed in the first spring support 81. This allows the first spring support 81 to hold the assist spring 60. A recess formed in the first spring support 81 allows the first spring support 81 to be mounted on the first spring base 80. The first spring base 80 is disposed below the first frame 30. The first spring base 80 is, for example, a sheet metal press work, a metal molded product, a resin molded product, or an integrally molded product of metal and resin. The first spring base 80 is welded or integrally molded on the first frame 30. The first spring support 81 is, for example, a metal molded product or a resin molded product. The first spring base 80 and the first spring support 81 are connected together by fitting.

In this manner, the one end 62 of the assist spring 60 is mounted on the first frame 30 through the first spring support 81. The other end 63 of the assist spring 60 is mounted on the second frame 40 through the second spring support 46. The leading end of the assist spring 60 is inserted into a hole formed in the second spring support 46. This allows the second spring support 46 to hold the assist spring 60. A recess formed in the second spring support 46 allows the second spring support 46 to be mounted on the second spring base 45.

In this manner, the first frame 30 and the second frame 40 are connected through the assist spring 60. This generates an urging force between the first frame 30 and the second frame 40. This assist spring 60 assists the sliding operation by the user. For example, an intermediate slide position between the closed state and the open state serves as a reference position. The slide is shifted from the reference position, thereby generating an urging force in one of the sliding directions. In the case of sliding from the intermediate position to the open state, an urging force is generated in the direction in which the slide is extended. On the other hand, in the case of sliding from the intermediate position to the closed state, an urging force is generated in the direction in which the slide retracts. In this manner, the assist spring 60 assists the sliding operation by the user.

The first spring base 80 is mounted on the first frame 30. The first spring base 80 is provided with a notch for holding the first spring support 81. The first spring base 80 is provided with a second stopper 82. The second stopper 82 contacts the link 50, thereby regulating the rotation of the link 50. This enables limitation of the tilt angle. The second stopper 82 contacts the link 50 in the vicinity of the open state. That is, since the first spring base 80 is mounted on the first frame 30, the second stopper 82 does not contact the link 50 in a state apart from the open state.

In the open state, for example, as shown in FIG. 4A, the first stopper 47 and the rib 50b contact each other. This regulates the rotation of the link 50 with respect to the second frame 40. Further, the second stopper 82 and the base portion 50a contact each other. This regulates the rotation of the link 50 with respect to the second frame 40. The first stopper 47 and the second stopper 82 regulate the rotation in the direction in which the link 50 rises, that is, the direction in which the tilt angle increases. Thus, in the open state, the stopper 47 and the stopper 82 contact the link 50, thereby preventing the tilt angle from increasing. At this time, the slide is located at a stroke end of the sliding action, that is, at the slide end position. The first stopper 47 and the second stopper 82 contact the link 50, thereby regulating the slide end in the extending direction. As a matter of course, each third pin 43 may define the slide end in the extending direction. The first stopper 47 and the second stopper 82 regulate the rotation of the link 50 at different positions from different directions.

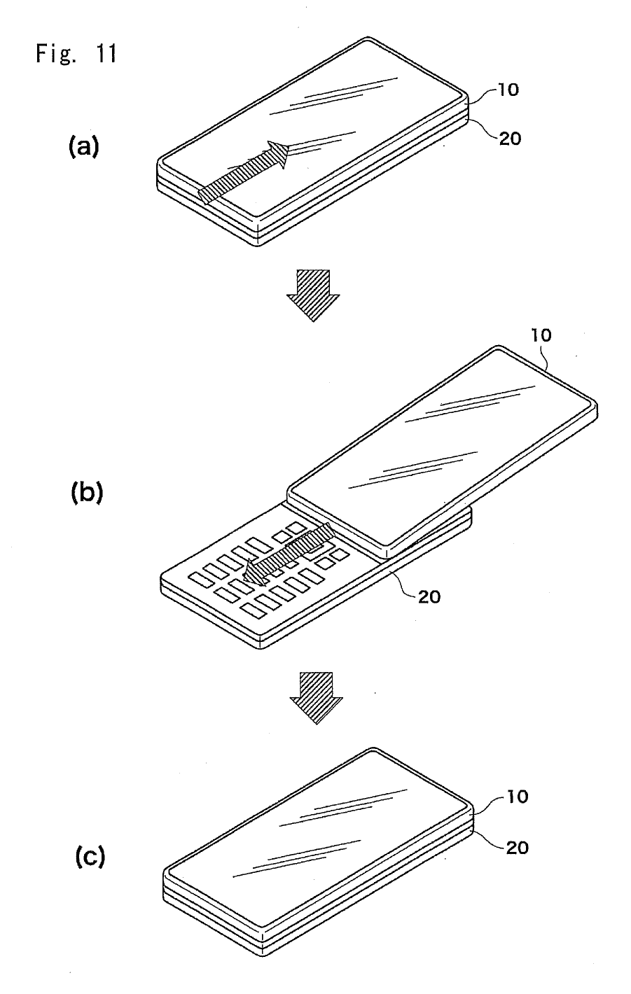

Referring next to FIGS. 11, the sliding operation of the mobile phone 1 will be described. FIG. 11(a) shows the closed state of the mobile phone 1. When a force is applied to the mobile phone 1, which is in the closed state, in the direction indicated by the arrow in FIG. 11(a) to allow the mobile phone to slide, the mobile phone shifts to the open state as shown in FIG. 11(b). In this state, the mobile phone 1 in the state where the tilt angle is large (hereinafter, the state is referred to as a high tilt angle state). Further, when a force is applied in the direction indicated by the arrow in FIG. 11(b) to allow the mobile phone to slide, the mobile phone shifts to the closed state as shown in FIG. 11(c).

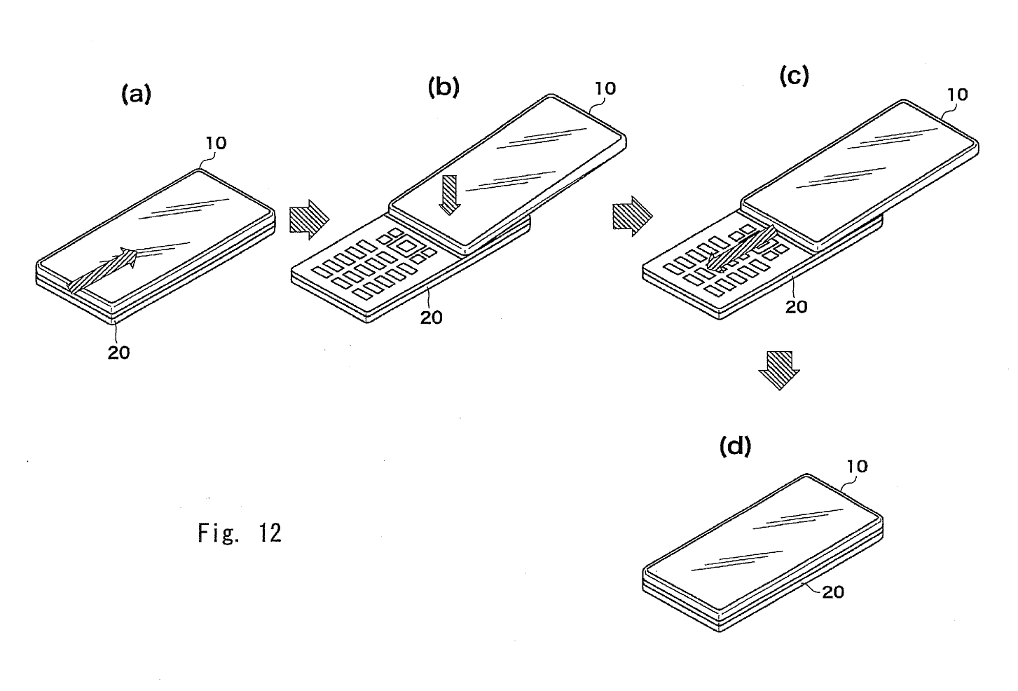

Referring to FIGS. 12, the sliding operation and tilting operation will be described. When the mobile phone is allowed to slide as shown in FIG. 11(a), the mobile phone 1 shifts to the open state shown in FIG. 12(b) from the closed state shown in FIG. 12(a). In this case, the mobile phone is in the high tilt angle state. In this state, for example, the display unit 11 is pressed to apply a force in the direction indicated by the arrow shown in FIG. 12(b). Specifically, a force is applied in the thickness direction of the mobile phone 1 to push the first casing 10 in the direction of the second casing 20. As a result, the tilt angle decreases as shown in FIG. 12(c). This state is referred to as a low tilt angle state. When the mobile phone is allowed to slide in the retracting direction as indicated by the arrow shown in FIG. 12(c), the mobile phone shifts to the closed state as shown in FIG. 12(d).

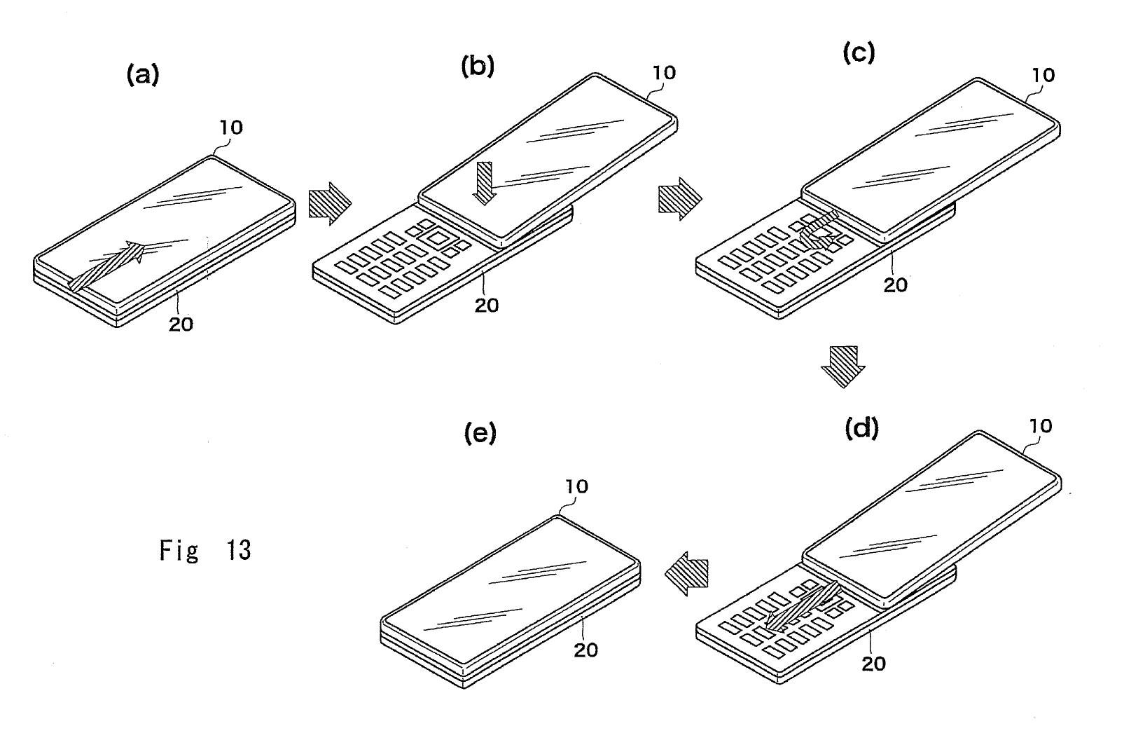

Referring to FIG. 13, the sliding operation and the tilting action will be described. As shown in FIG. 11(a), the mobile phone 1 shifts from the closed stare shown in FIG. 13(a) to the open state shown in FIG. 13(b). In this case, the mobile phone is in the high tilt angle state. In this state, as shown in FIG. 12(b), when the display unit 11 is pushed, the tilt angle decreases as shown in FIG. 13(c). In this state, the mobile phone 1 is in the low tilt angle state. The first casing 10 is slightly drawn in the direction indicated by the arrow shown in FIG. 13(c) and is then released. For example, the first casing 10 is drawn in the sliding direction only by a small distance and is then released. Thus, as shown in FIG. 13(d), the mobile phone returns to the high tilt angle state. Further, when the mobile phone is allowed to slide in the direction indicated by the arrow shown in FIG. 13(d), the mobile phone shifts to the closed state as shown in FIG. 13(e).

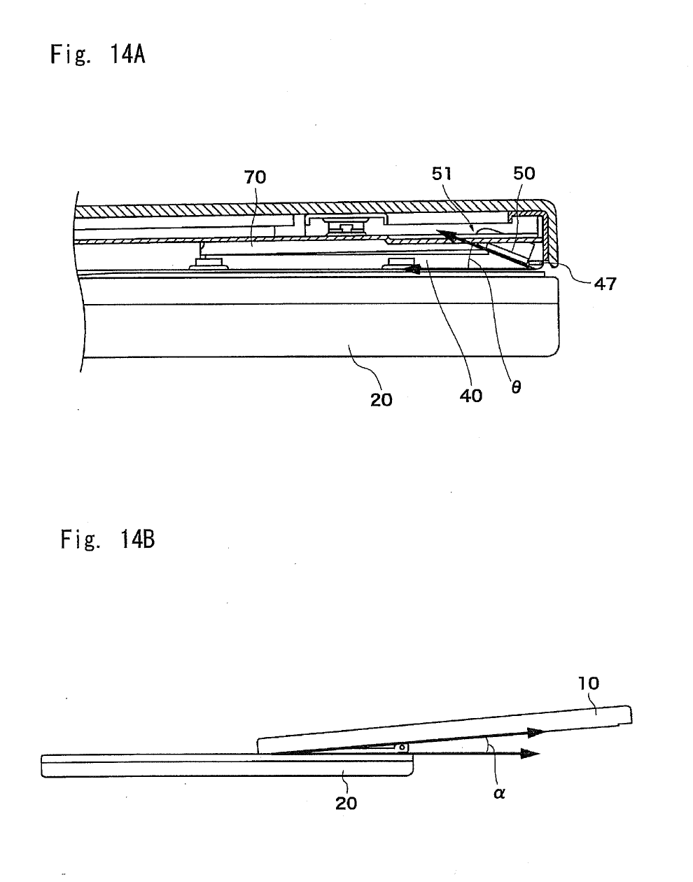

The angle of the link 50 and the tilt angle in the action described above will be described. First, as shown in FIGS. 14A and 14B, a link angle θ and a tilt angle α are defined. The link angle θ is an angle of the link 50 with respect to the front surface of the second casing 20, and the tilt angle α is an angle formed between the front surface of the second casing 20 and the back surface of the first casing 10. Referring to FIG. 14A, the link angle θ is an angle formed counterclockwise from the link 50 to the front surface of the second casing 20.

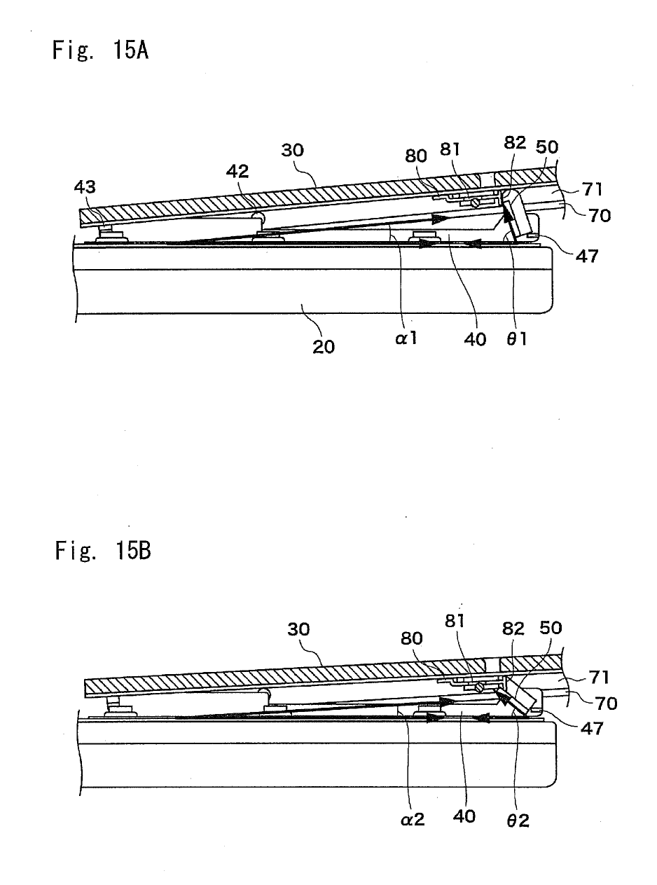

In the high tilt angle state, the mobile phone 1 is in the state as shown in FIG. 15A. In the high tilt angle state, the urging force of the assist spring 60 is applied in the extending direction. In the high tilt angle state, the link angle is defined as a link angle θ1 and the tilt angle is defined as a tilt angle al. In this case, the first stopper 47 contacts the front surface of the link 50, and the second stopper 82 contacts the back surface of the link 50. Note that in FIGS. 14A, 14B, 15A, and 15B, the right side of the link 50 corresponds to the front side in the sliding direction, and the left side of the link 50 corresponds to the back side in the sliding direction. Accordingly, in FIGS. 14A, 14B, 15A, and 15B, the right side is referred to as the front side and the left side is referred to as the back side.

In the low tilt angle state, the mobile phone 1 is in the state as shown in FIG. 15B. In the low tilt angle state, the link angle is defined as a link angle θ2 and the tilt angle is defined as a tilt angle α2. In this case, the second stopper 82 contacts the link 50 at the front side of the link 50. The link angle θ2 is smaller than the link angle θ1. That is, in the low tilt angle state, the link 50 is allowed to fall to a larger degree than in the high tilt angle state. The slide position in the high tilt angle state and the slide position in the low tilt angle state are substantially the same or slightly shifted from each other. Accordingly, the slide position in the high tilt angle state and the slide position in the low tilt angle state are the same or close to each other. That is, the slide position in each of the high tilt angle state and the low tilt angle state substantially matches the slide end.

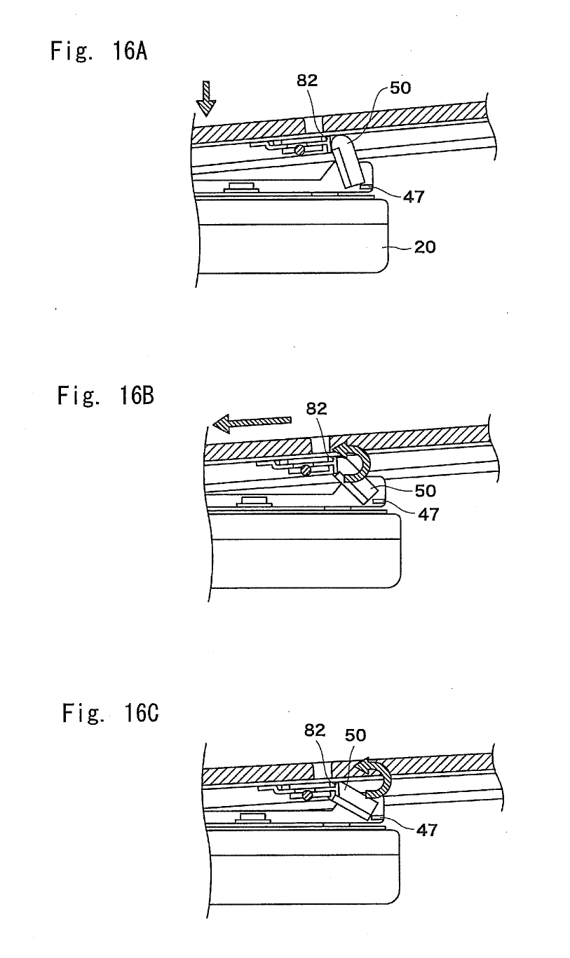

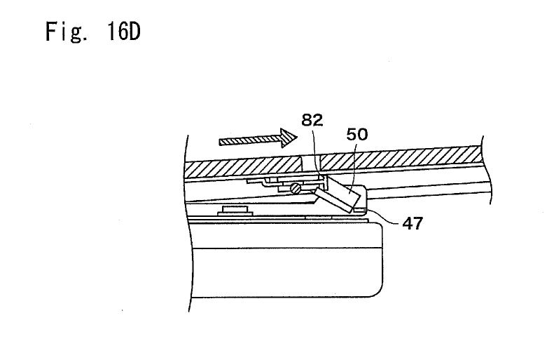

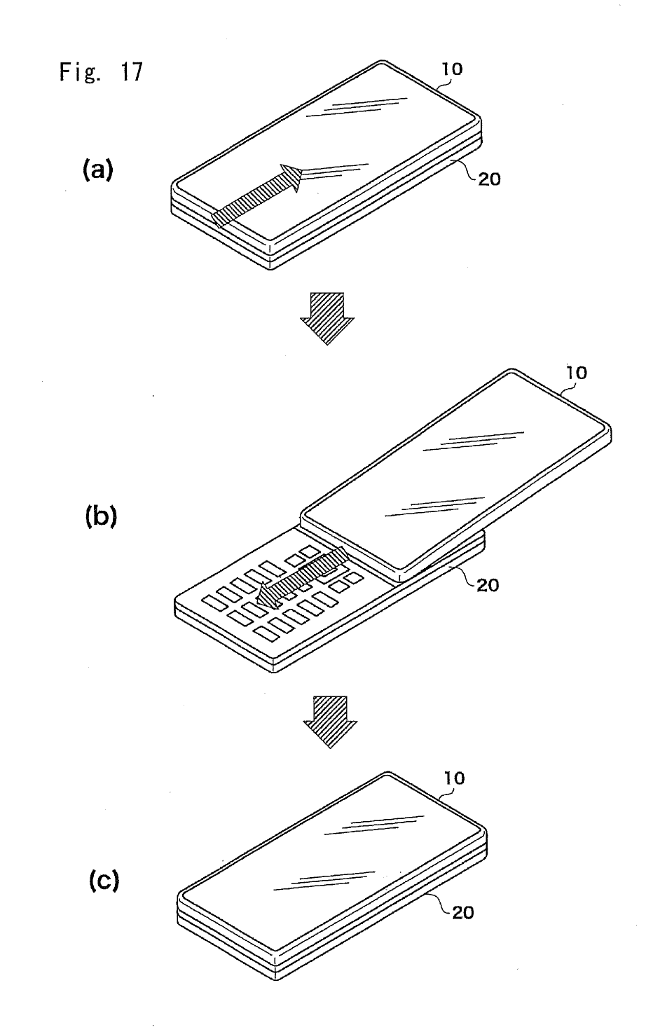

Next, the action obtained by the sliding operation and tilting operation will be described with reference to FIGS. 16A to 16D. When the user causes the mobile phone 1 to slide from the closed state, the mobile phone 1 shifts to the open state shown in FIG. 16A. FIG. 16A shows the high tilt angle state. When the mobile phone is caused to further slide toward the open state, the first stopper 47 contacts the link 50. Further, the second stopper 82 contacts the link 50. This stops the sliding. The first stopper 47 and the second stopper 82 regulate rising of the link 50. In this state, the urging force of the assist spring 60 is generated in the extending direction. The urging force of the assist spring 60 allows the link 50 to be pressed against each of the first stopper 47 and the second stopper 82. The urging force of the assist spring 60 allows the link 50 to be pressed against each of the first stopper 47 and the second stopper 82, thereby maintaining the link angle θ1. Thus, the mobile phone shifts to the high tilt angle state.

Further, the user presses the first casing 10 in the direction of the second casing 20 (direction indicated by the arrow shown in FIG. 16A) so as to change the tilt angle. Then, the force applied by the user exceeds the urging force of the assist spring 60, which allows the link 50 contacting the front side of the second stopper 82 to rotate. Accordingly, the link 50 moves in the direction in which the link angle 01 decreases, That is, the contact between the second stopper 82 and the link 50 is slightly released, so that the link 50 is brought into a movable state (see FIG. 16B). At this time, the rails 70 slightly slide and move toward each of the first pins 51, the second pins 42, and the third pins 43. Then, the link 50 rotates to follow the sliding (as indicated by the circular arrow shown in FIG. 16B). That is, the link 50 rotates in the falling direction, while being in close contact with the second stopper 82. The link 50 rotates in the falling direction along the grooves 71 of the rails 70. In this manner, the pressing operation by the user allows the first stopper 47 and the second stopper 82 to be temporarily spaced away from the link 50, thereby changing the link angle.

As shown in FIG. 16C, the mobile phone is caused to slide until the regulation by the second stopper 82 is released. As a result, the link 50 rotates to such a degree that the link 50 is spaced apart from the front side of the second stopper 82. When the user stops the operation of pressing the first casing 10, the mobile phone is allowed to slide in the extending direction by the urging force of the assist spring 60 as indicated by the arrow shown in FIG. 16D. Then, the link 50 rotates to rise. At this time, the link 50 contacts the back side of the second stopper 82. Further, the link 50 contacts the first spring support 81 or the vicinity of the first spring support 81. In this case, the first spring support 81 functions as a part of the second stopper 82. Furthermore, the first stopper 47 contacts the link 50.

This results in stopping the rotation of the link 50 in the direction in which the link 50 rises. In other words, the second stopper 82 and the first stopper 47 prevent the tilt angle from increasing. The sliding due to the urging force of the assist spring 60 is also stopped. In this manner, the urging force from the assist spring 60 allows the link 50 to be pressed against each of the first stopper 47 and the second stopper 82. In this state, the urging force of the assist spring 60 with respect to the first frame 30 is generated in the direction indicated by the arrow shown in FIG. 16D. Accordingly, the urging force is applied in the direction in which the slide is extended. The urging force of the assist spring 60 allows the link 50 to be pressed against the second stopper 82, thereby maintaining the link angle θ2 and bringing the mobile phone into the low tilt angle state.

In this manner, the first stopper 47 and the second stopper 82 regulate the rotation of the link. Thus, the tilt angle can be changed by a simple operation. Therefore, the operability can be improved. The slide position in the high tilt angle state and the slide position in the low tilt angle state are substantially the same. This enables an input operation using the input keys of the input unit 21 in any tilt state.

Note that the first stopper 47 is provided to the second frame 40. The first stopper 47 and the second frame 40 may be separately provided, as a matter of course. In this case, the first stopper 47 is provided to the second frame 40. Meanwhile, the second stopper 82 is provided to the first frame 30. That is, the second stopper 82 is mounted on the first frame 30 through the first spring base 80. That is, the second stopper 82 is fixed to the first frame 30. The second stopper 82 and the first frame 30 may be formed as an integral product, as a matter of course. This improves the operability with a simple configuration. Note that stoppers are preferably provided at both ends of the link 50. In this case, two stoppers, i.e., the first stopper 47 and the second stopper 82, are provided.

Further, the link 50 contacts the second stopper 82 with different angles in each of the high tilt angle state and the low tilt angle state. At this time, the position where the link 50 of the second stopper 82 contacts varies. Specifically, in the high tilt angle state, the link contacts on the front surface of the base portion 50a shown in FIG. 7, while in the low tilt angle state, the link contacts on the back surface thereof. Further, the second stopper 82 regulates the rotation in the direction in which the link 50 rises. This makes it possible to maintain the high tilt angle state and the low tilt angle state.

According to the configuration described above, the tilt angle can be changed simply. Specifically, the tile angle can be switched only by slightly pressing the surface of the first casing 10 on which the display unit 11 is disposed. Further, the tilt angle can be switched only by the operation in which the casing including the display unit is slightly drawn in the closing direction and is then released.

According to the configuration described above, the mobile phone 1 can be reduced in thickness. The first stopper 47 and the second stopper 82 are arranged in the movable area of the assist spring 60 which is provided so as not to interfere with the casing. Further, the first stopper 47 and the second stopper 82 can be formed of a part of the existing components. Specifically, the first stopper 47 is formed as a part of the second frame 40, and the second stopper 82 is formed as a part of the first spring base 80. Consequently, the mobile phone 1 can be reduced in thickness.

### Second Exemplary Embodiment

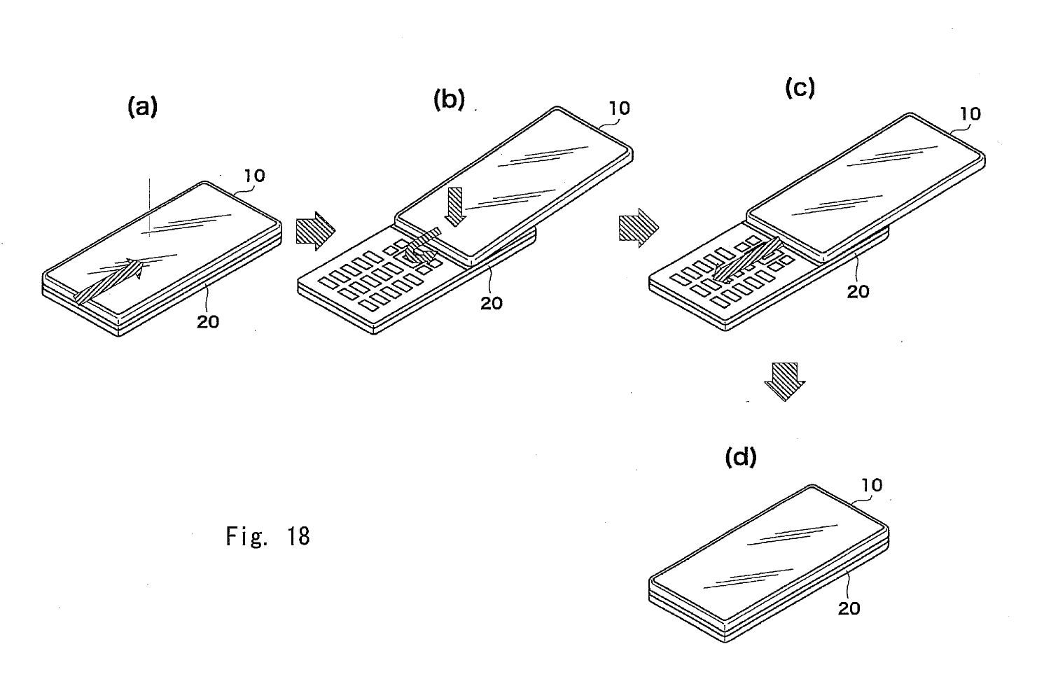

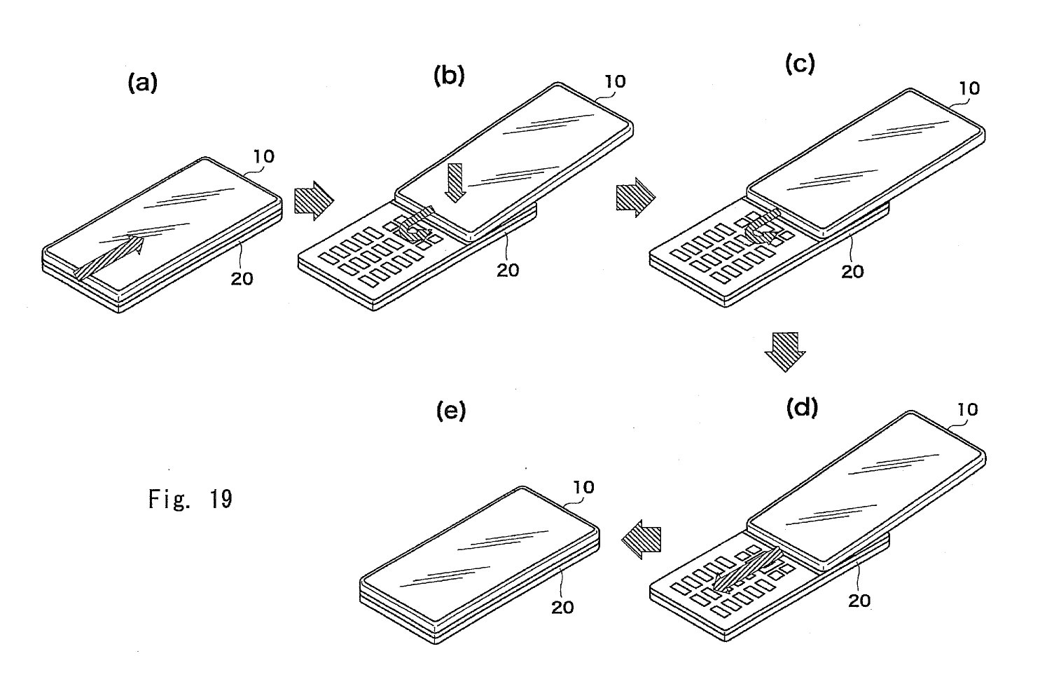

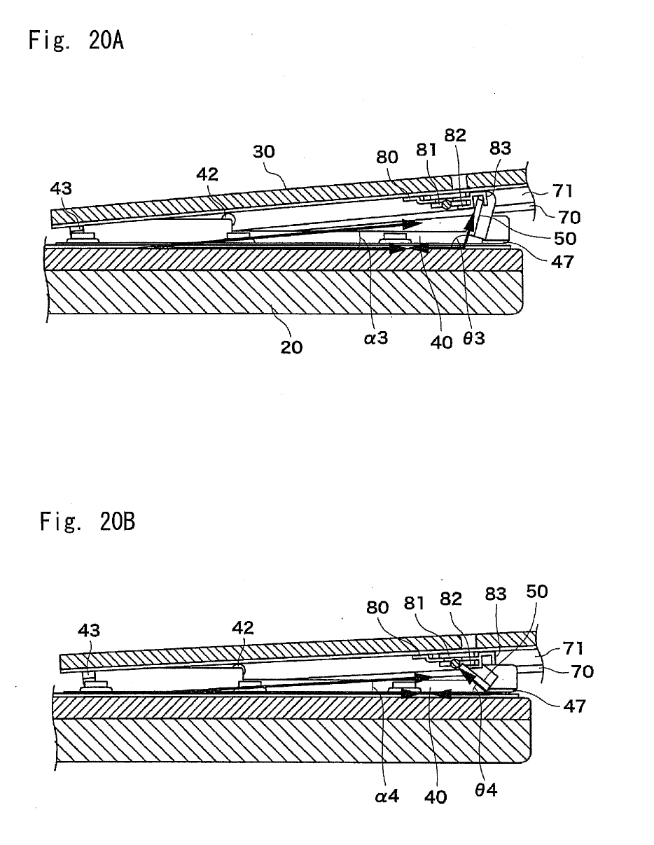

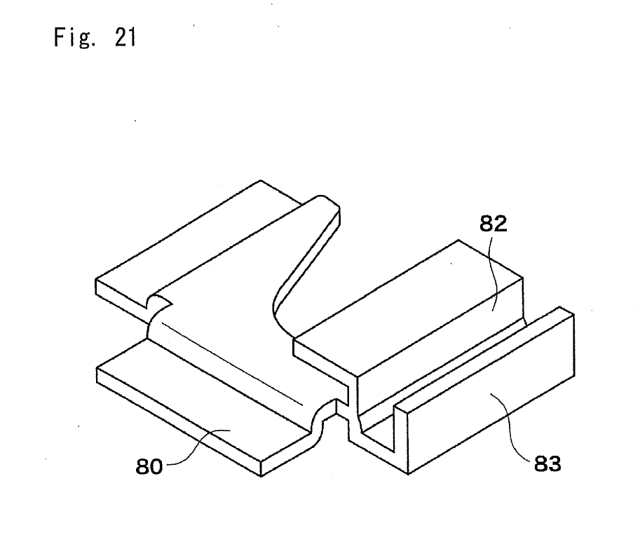

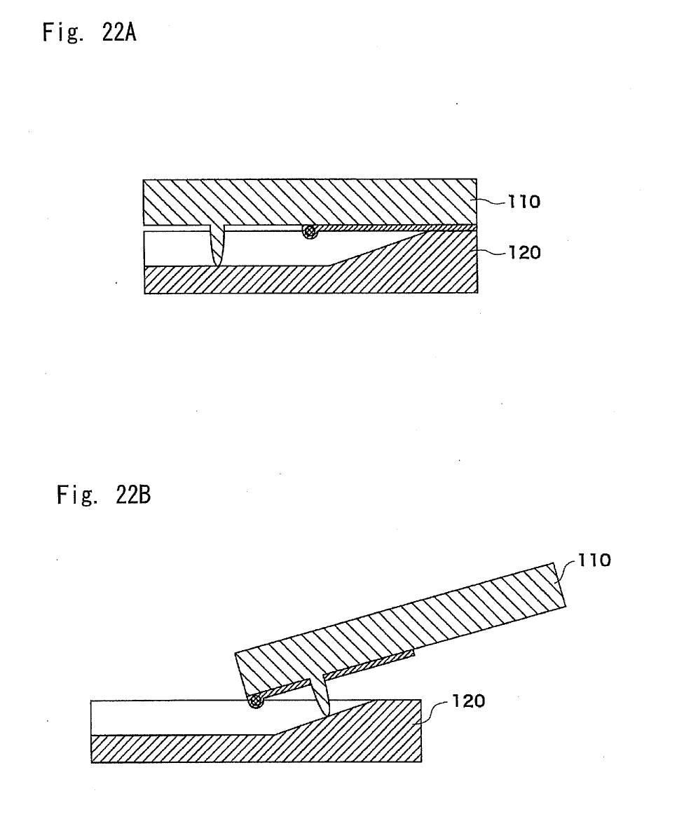

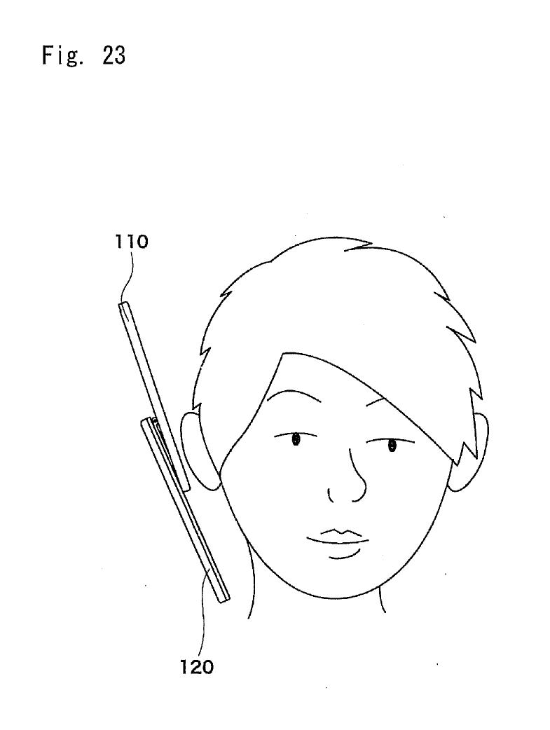

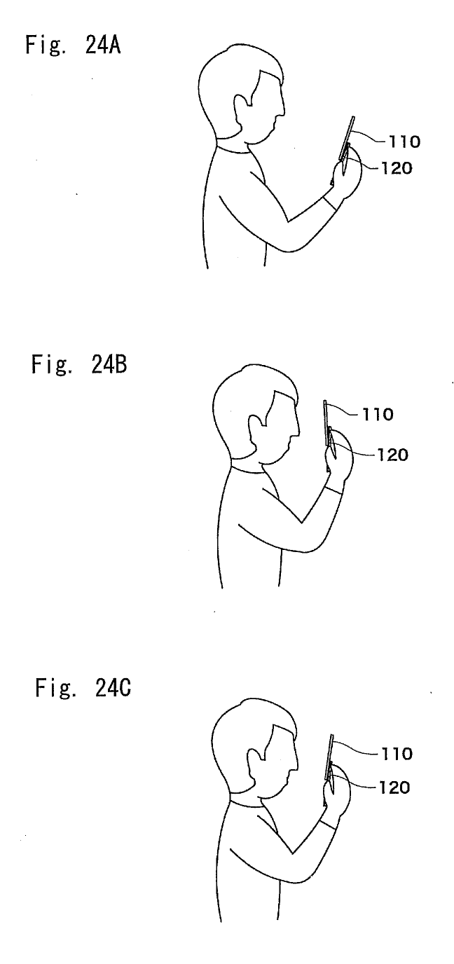

A sliding mechanism of a mobile phone according to this exemplary embodiment will be described with reference to FIGS. 17 to 21. FIGS. 17 are views showing the sliding operation of the mobile phone. FIGS. 18 are views showing the sliding operation and tilting operation. FIGS. 19 are views showing the sliding operation and tilting operation. Note that the basic configuration of the sliding mechanism of the mobile phone according to this exemplary embodiment is the same as that of the first exemplary embodiment, so the description thereof is omitted as needed. In this exemplary embodiment the user operation for changing the tilt angle is different. Accordingly, as shown in FIGS. 20A, 20B, and 21, not only the second stopper 82, but also a third stopper 83 is formed on the first spring base 80. Note that the third stopper 83 and the second stopper 82 may be integrally formed with the first spring base 80.

In this exemplary embodiment, the operation for changing the tilt angle and the action in association with the operation are different from those of the first exemplary embodiment. As shown in FIGS. 17, the action obtained by the sliding operation is similar to that of the first exemplary embodiment. That is, the action shown in FIG. 11 allows the mobile phone to shift from the open state to the closed state, or from the closed state to the open state.

In this exemplary embodiment, the operation for changing the tilt angle from the open state shown in FIG. 18(b) is different from that of the first exemplary embodiment. In this exemplary embodiment, the first casing 10 is drawn in and is then pressed into the second casing, thereby enabling the mobile phone to shift from the high tilt angle state to the low tilt angle state. Accordingly, even when the first casing 10 is pressed into the second casing 20 in the high tilt angle state, the tilt angle does not change. This operation will be described later.

In the case of shifting from the high tilt angle state to the low tilt angle state, the user slightly draws in the first casing 10 and then slightly presses it into the second casing. This allows the mobile phone 1 to shift from the high tilt angle state shown in FIG. 18(b) to the low tilt angle state shown in FIG. 18(c). Specifically, the user first causes the first casing 10 to slightly slide in the retracting direction. This enables the link 50 to be released from the third stopper 83, as described later. In this state, the first casing 10 is pressed into the second casing 20. This allows the link 50 to rotate and shift to the low tilt angle state. Sliding in the retracting direction from the low tilt angle state brings the mobile phone into the closed state (FIG. 18(d)).

Next, the operation in the case of shifting from the low tilt angle state to the high tilt angle state will be described with reference to FIGS. 19. First, as in FIGS. 18(a) to 18(c), the mobile phone is caused to shift to the low tilt angle state through the high tilt angle state (FIG. 19(a) to FIG. 19(c)). Then, as in the first exemplary embodiment, the user slightly draws in the first casing 10 and then releases it. As a result, as shown in FIG. 19(d), the state returns to the high tilt angle state. Then, when the mobile phone is caused to slide in the retracting direction, the mobile phone shifts to the closed state as shown in FIG. 19 (e).

The action of the link 50 in the case of changing the tilt angle will be described with reference to FIGS. 20A, 20B, and 21. In this exemplary embodiment, as shown in FIG. 21, the shape of the first spring base 80 is different from that of the first exemplary embodiment. That is, the second stopper 82 and the third stopper 83 are provided on the first spring base 80. The third stopper 83 is disposed at the front side of the second stopper 82. The second stopper 82 and the third stopper 83 form a groove having a U-shaped cross section. In this groove, the base portion 50a of the link 50 is inserted (see FIG. 20A). That is, the leading end of the link 50 is inserted between the second stopper 82 and the third stopper 83. Accordingly, the link 50 contacts the third stopper 83. At this time, the second stopper 82 and the link 50 may contact each other.

Specifically, as shown in FIG. 20A, a link angle θ3 is an obtuse angle in the open state. The base portion 50a of the link 50 is inserted into the U-shaped portion formed by the third stopper 83 and the second stopper 82. Accordingly, even when the first casing 10 is pressed into the direction of the second casing 20 in the open state, the link 50 does not rotate. Thus, the high tilt angle state is maintained even when the first casing 10 is pressed. Therefore tire tilt anglers prevented from being change by an unintentional operation by the user. For example, even if the first casing 10 is pressed accidentally, the tilt angle does not change. This leads to improvement in the operability.

When the first casing is caused to slide in the retracting direction in the high tilt angle state, the link 50 is released from the third stopper 83 and the first stopper 47. This brings the link 50 into a rotatable and movable state. Sliding in the retracting direction changes the positions of the first pins 51, the second pins 42, and the third pins 43 with respect to the rails 70. Accordingly, the tilt angle changes and the link 50 rotates counterclockwise. In this case, after the link 50 rises vertically and a link angle θ4 becomes 90 degrees, the link angle θ4 becomes an acute angle. When the user stops applying a force, the link 50 adds a force in the extending direction to the second stopper 82 by the urging force of the assist spring 60. As a result, the state shown in FIG. 20B is obtained. In this state, as in FIG. 15B, the second stopper 82 contacts the link 50 to regulate the rotation direction. In the case of shifting from the low tilt angle state to the high tilt angle state, the user performs operation in the same manner as in the first exemplary embodiment. This allows the link 50 to be temporarily released from the second stopper 82 and the first stopper 47. Then, the mobile phone returns to the state shown in FIG. 15A.

In this exemplary embodiment, the rotation of the link 50 is regulated by the third stopper 83 when the first casing 10 is pressed in the direction of the second casing 20 in the thickness direction. That is, the third stopper 83 regulates the rotation of the link 50 when the first frame 30 receives the force that presses the first frame 30 into the second frame 40 in the thickness direction. Accordingly, even if the first casing 10 is pressed accidentally, the tilt angle does not change. This leads to improvement in the operability. Further, formation of the second stopper 82 and the third stopper 83 as the same component enables reduction in the number of components.

According to the configuration described above, the tilt angle can be switched simply. That is, the operation in which the display surface of the first casing 10 on which the display unit 11 is disposed is slightly drawn in the retracting direction and is then pressed enables switching of the tilt angle. Further, the operation in which the first casing 10 including the display unit 11 is slightly drawn in the retracting direction and is then released enables shifting from the low tilt angle state to the high tilt angle state. The operation of drawing in the retracting direction is only necessary for shifting from the open state to the closed state. This leads to improvement in the operability.

Furthermore, according to the configuration described above, the mobile phone 1 can be reduced in thickness. The the first stopper 47, the second stopper 82, and the second stopper 83 are arranged in the movable area of the assist spring 60 which is provided so as not to interfere with the casing. Further, the first stopper 47, the second stopper 82, and the second stopper 83 can be formed of a part of the existing components. Specifically, the first stopper 47 is formed as a part of the second frame 40, and the second stopper 82 and the third stopper 83 are formed as a part of the first spring base 80. This contributes to a reduction in thickness of the mobile phone 1.

As shown in the first and second exemplary embodiments, the tile angle can be easily changed by the action of the link 50. That is, the tilt angle is changed by one-time operation, which improves the operability. Note that the first and second exemplary embodiments can be combined as needed. The sliding structure described above is not limited to the mobile phone 1, but can be used for other portable electronic devices, as a matter of course. The sliding structure can also be implemented in portable electronic devices such as a portable game device, a portable computer, a portable music player, a desktop computer, and various remote controllers for television/video/air conditioner or the like. In the slide-type mobile phone in which a certain tilt angle is formed between the first casing 10 including the display unit 11 and the second casing 20 including the input keys, the tilt angle can be easily switched.

Though the present invention has been described above with reference to exemplary embodiments, the present invention is not limited to the above exemplary embodiments. The configuration and details of the present invention can be modified in various manners which can be understood by those skilled in the art within the scope of the invention.

This application is based upon and claims the benefit of priority from Japanese patent application No. 2010-116124, filed on May 20, 2010, the disclosure of which is incorporated herein in its entirety by reference.

### INDUSTRIAL APPLICABILITY

A technique according to the present invention can be applied to portable devices, for example.

### REFERENCE SIGNS LIST

1 MOBILE PHONE
10 FIRST CASING
11 DISPLAY UNIT
20 SECOND CASING
21 INPUT UNIT
22 SCREW HOLE
30 FIRST FRAME
31 SCREW HOLE
32 NOTCH
33 LONG HOLE
40 SECOND FRAME
41 SCREW BOSS
42 SECOND PIN
43 THIRD PIN
44 SHAFT HOLE
45 SECOND SPRING BASE
46 SECOND SPRING SUPPORT
47 FIRST STOPPER
50 LINK
50a BASE UNIT
50b RIB
51 FIRST PIN
52 SHAFT
60 ASSIST SPRING
61 SPIRAL PORTION
62 ONE END
63 THE OTHER END
70 RAIL
71a SLIDE GROOVE
71a LINEAR PORTION
71b TILT PORTION
72 CURVED PORTION
73 FIXING PORTION
80 FIRST SPRING BASE
81 FIRST SPRING SUPPORT
82 SECOND STOPPER
83 THIRD STOPPER
100 HINGE UNIT
110 FIRST CASING
120 SECOND CASING

1. A sliding mechanism comprising:
a first frame provided with a slide rail having a sliding direction that changes;
a second frame that slides along the slide rail;
an elastic member that generates an urging force between the first frame and the second frame according to a slide position of each of the first frame and the second frame;
a link that is mounted slidably with respect to the slide rail and rotates to change a tilt angle of the first frame with respect to the second frame;
a first stopper that regulates the rotation of the link; and
a second stopper that regulates the rotation of the link from a direction different from that of the first stopper.

2. The sliding mechanism according to claim 1, wherein a contact position of the second stopper with respect to the link changes at a first slide position to allow the link to be inclined at a different angle, thereby switching the tilt angle.

3. The sliding mechanism according to claim 1, wherein the first stopper is provided to the second frame, and the second stopper is provided to the first frame.

4. The sliding mechanism according to claim 1, wherein
the elastic member generates an urging force in a direction assisting a sliding operation by a user, and
at a first slide position, the link is pressed against each of the first stopper and the second stopper by the urging force of the elastic member.

5. The sliding mechanism according to claim 1, wherein
in a state where a tilt angle at a first slide position is large, the rotation of the link in a first rotational direction is regulated, and
in a state where the tilt angle at the first slide position is small, the rotation of the link in the first rotational direction is regulated.

6. The sliding mechanism according to claim 5, wherein
in the state where the tilt angle at the first slide position is large, each of the first stopper and the second stopper contacts the link, and
in the state where the tilt angle at the first slide position is small, each of the first stopper and the second stopper contacts the link.

7. The sliding mechanism according claim 1, further comprising a third stopper that regulates a rotation in a first rotational direction of the link, wherein
in a state where a tilt angle at a first slide position is large, the third stopper regulates the rotation in the first rotational direction of the link, and
in a state where the tilt angle at the first slide position is small, the second stopper regulates the rotation in the first rotational direction of the link.

8. The sliding mechanism according to claim 7, wherein the third stopper regulates the rotation of the link, upon receiving a force that presses the first frame into the second frame in a thickness direction of the sliding mechanism.

9. The sliding mechanism according to claim 1, wherein
a spring base connected with the elastic member is provided on the first frame, and
the second stopper is formed on a part of the spring base.

10. A portable device comprising:
a sliding mechanism according to claim 1;
a first casing mounted on the first frame; and
a second casing mounted on the second frame.

11. The sliding mechanism according to claim 2, wherein the first stopper is provided to the second frame, and the second stopper is provided to the first frame.

12. The sliding mechanism according to claim 2, wherein
the elastic member generates an urging force in a direction assisting a sliding operation by a user, and
at a first slide position, the link is pressed against each of the first stopper and the second stopper by the urging force of the elastic member.

13. The sliding mechanism according to claim 3, wherein
the elastic member generates an urging force in a direction assisting a sliding operation by a user, and
at a first slide position, the link is pressed against each of the first stopper and the second stopper by the urging force of the elastic member.

14. The sliding mechanism according to claim 2, wherein
in a state where a tilt angle at a first slide position is large, the rotation of the link in a first rotational direction is regulated, and
in a state where the tilt angle at the first slide position is small, the rotation of the link in the first rotational direction is regulated.

15. The sliding mechanism according to claim 3, wherein
in a state where a tilt angle at a first slide position is large, the rotation of the link in a first rotational direction is regulated, and
in a state where the tilt angle at the first slide position is small, the rotation of the link in the first rotational direction is regulated.

16. The sliding mechanism according to claim 2, further comprising a third stopper that regulates a rotation in a first rotational direction of the link, wherein
in a state where a tilt angle at a first slide position is large, the third stopper regulates the rotation in the first rotational direction of the link, and
in a state where the tilt angle at the first slide position is small, the second stopper regulates the rotation in the first rotational direction of the link.

17. The sliding mechanism according to claim 3, further comprising a third stopper that regulates a rotation in a first rotational direction of the link, wherein
in a state where a tilt angle at a first slide position is large, the third stopper regulates the rotation in the first rotational direction of the link, and
in a state where the tilt angle at the first slide position is small, the second stopper regulates the rotation in the first rotational direction of the link.

18. The sliding mechanism according to claim 4, further comprising a third stopper that regulates a rotation in a first rotational direction of the link, wherein
in a state where a tilt angle at a first slide position is large, the third stopper regulates the rotation in the first rotational direction of the link, and
in a state where the tilt angle at the first slide position is small, the second stopper regulates the rotation in the first rotational direction of the link.

19. The sliding mechanism according to claim 2, wherein
a spring base connected with the elastic member is provided on the first frame, and
the second stopper is formed on a part of the spring base.

20. The sliding mechanism according to claim 3, wherein
a spring base connected with the elastic member is provided on the first frame, and
the second stopper is formed on a part of the spring base.
